(19) United States
(12) Patent Application Publication
(10) Pub. No.: US 2009/0095961 A1
(43) Pub. Date: Apr. 16, 2009

(54) Combination of LED and heat dissipation device

(75) Inventor: Yaw-Huey Lai, Taipei County (TW)

Correspondence Address: BACON & THOMAS, PLLC, 625 SLATERS LANE, FOURTH FLOOR, ALEXANDRIA, VA, 22314-1176, US

(73) Assignee: TAI-SOL ELECTRONICS CO., LTD., TAIPEI CITY (TW)

(21) Appl. No.: 11/987,820

(22) Filed: Dec. 5, 2007

(30) Foreign Application Priority Data
Oct. 11, 2007 (TW) 96217008

(51) Int. Cl. H01L 33/00

(52) U.S. Cl. 257/88; 257/E33.075

(57) ABSTRACT

A combination of LED and heat dissipating device includes a heat dissipating device, an electrically insulative thermal conductivity layer covered on a part of the surface of the heat dissipating device, thermal and electric conducting layers disposed at the electrically insulative thermal conductivity layer and electrically isolated from one another, LED units each having an LED unit installed in one thermal and electric conducting layer and a lead wire that connects the LED chip of the respective LED unit to the LED chip of another LED unit, and a packaging device covering the LED units.

### BACKGROUND OF THE INVENTION

1. Field of the Invention

The present invention relates to LED (light emitting diode) and heat dissipation technology and more particularly, to a combination of LED and heat dissipation device.

2. Description of the Related Art

High brightness LEDs (light emitting diodes) produce much heat energy during operation. Therefore, how to solve heat dissipation problem during light emitting operation of LEDs is an important subject to people in this art. Taiwan Patent M313,759 discloses a technique of installation of LED chips in a heat sink for direct transfer of heat energy from the LED chips to the heat sink for quick dissipation.

The aforesaid Taiwan Patent M313,759 solves heat the dissipation problem, however because the negative electrodes of the LED chips are directly installed in the heat sink, the LED chips are arranged in a parallel status when their positive electrodes are connected to a circuit.

When all the LED chips are arranged in parallel, the total resistance is greatly reduced, requiring a low voltage and a high current. If the number of the LED chips is increased, the demand for current will be relatively increased while the demand for voltage remains unchanged. This condition will cause a trouble in the control of the driving power, i.e., it is difficult to satisfy the demand for low voltage and high current. Further, this arrangement will also cause extra heat energy, wasting much heat dissipation resource.

### SUMMARY OF THE INVENTION

The present invention has been accomplished under the circumstances in view. It is one object of the present invention to provide a combination of LED and heat dissipation device that has LED chips installed in a heat dissipation device in a series manner, providing excellent heat dissipation effect and facilitating the control of the driving power.

To achieve this and other objects of the present invention, the combination of LED and heat dissipating device comprises a heat dissipating device; an electrically insulative thermal conductivity layer covered on at least a part of the surface of the heat dissipating device; a plurality of thermal and electric conducting layers disposed at the electrically insulative thermal conductivity layer and electrically isolated from one another; a plurality of LED units, the LED units each comprising an LED chip and at least one lead wire, the LED chip of each of the LED units being installed in one of the thermal and electric conducting layers, the at least one lead wire of each of the LED units each having one end connected to the LED chip of the respective LED unit and an opposite end connected to the LED chip of another one of the LED units such that the LED chips of the LED units are connected in series; and at least one packaging device covering the LED units.

### BRIEF DESCRIPTION OF THE DRAWINGS

FIG. 1 is an elevational assembly view of a combination of LED and heat dissipating device in accordance with a first embodiment of the present invention.

FIG. 2 is a top view of the combination of LED and heat dissipating device in accordance with a first embodiment of the present invention.

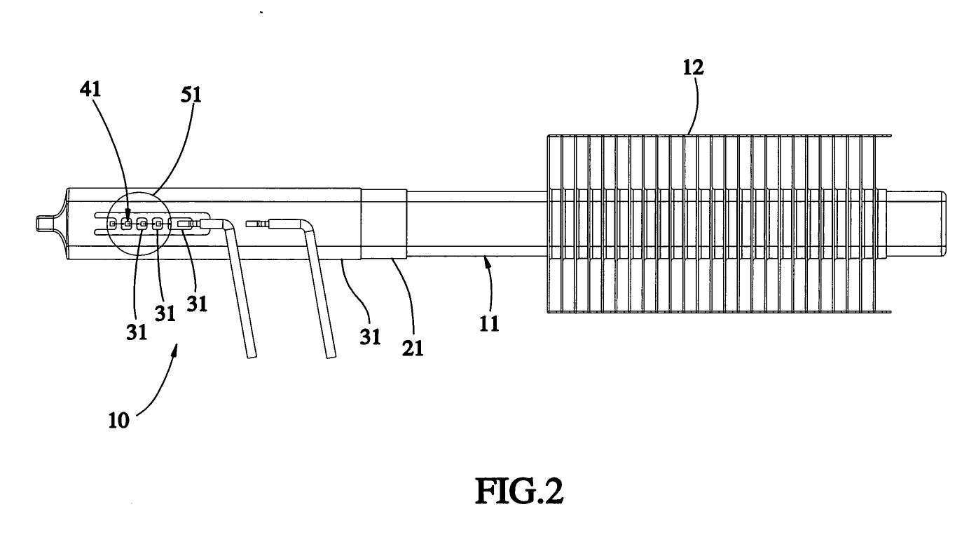

FIG. 3 is a side view of the combination of LED and heat dissipating device in accordance with a first embodiment of the present invention.

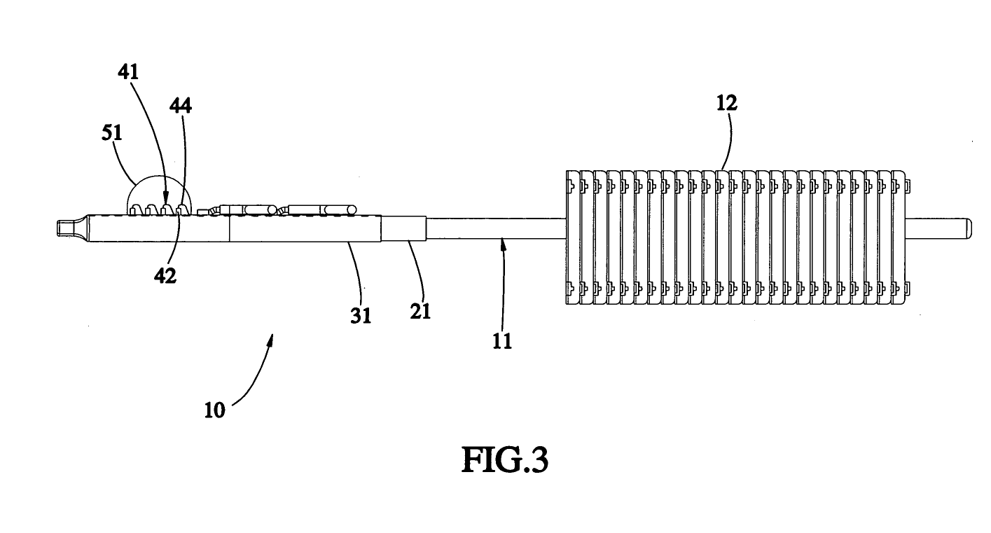

FIG. 4 is a schematic sectional view of the combination of LED and heat dissipating device in accordance with a first embodiment of the present invention.

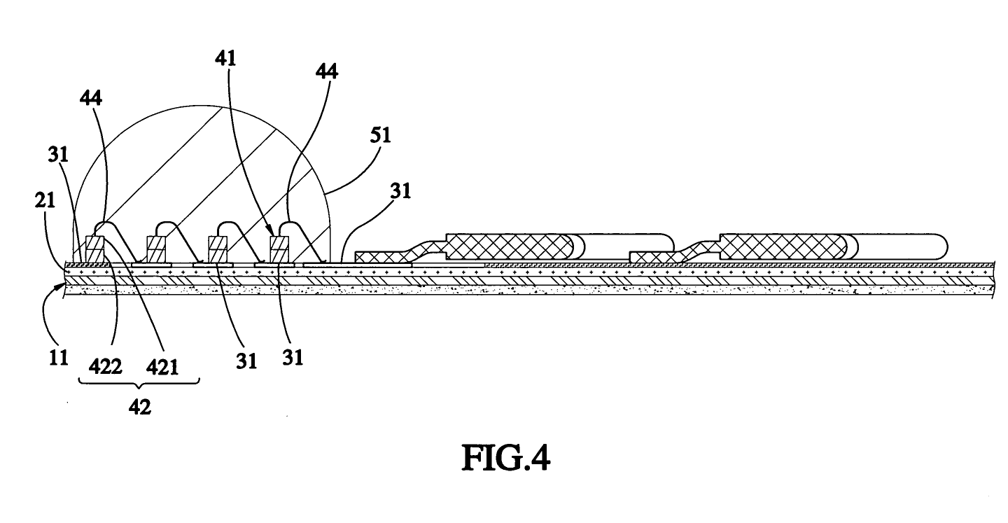

FIG. 5 corresponds to FIG. 1 but showing LED chips connected into series and multiple LED series connected in parallel.

FIG. 6 is a top view of FIG. 5.

FIG. 7 is an elevational assembly view of a combination of LED and heat dissipating device in accordance with a second embodiment of the present invention.

FIG. 8 is an elevational assembly view of a combination of LED and heat dissipating device in accordance with a third embodiment of the present invention.

### DETAILED DESCRIPTION OF THE INVENTION

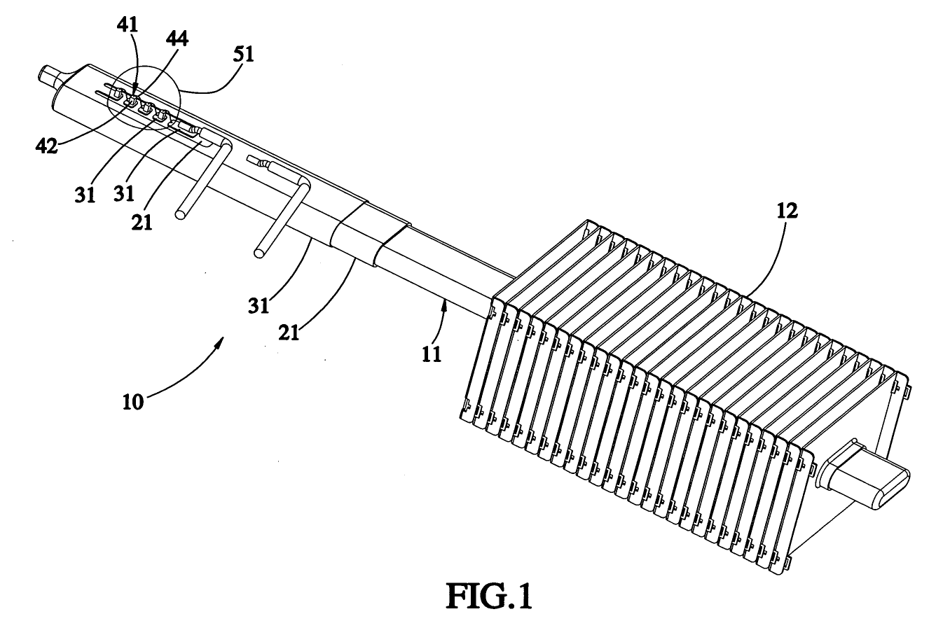

Referring to FIGS. 1˜4, a combination of LED and heat dissipating device 10 in accordance with a first embodiment of the present invention is shown comprised of a heat dissipating device 11, an electrically insulative thermal conductivity layer 21, multiple thermal and electric conducting layers 31, multiple LED units 41, and at least one packaging device 51.

The heat dissipating device 11 can be a liquid/gas phase heat dissipating device, heat sink, thermal conductivity metal rod, or their combination. According to this embodiment, the heat dissipating device 11 is a liquid/gas phase heat dissipating device, for example, a heat tube having a plurality of radiation fins 12 arranged on its one end.

The electrically insulative thermal conductivity layer 21 is formed of epoxy resin and covered on the surface of the heat dissipating device 11.

The thermal and electric conducting layers 31 are copper plates disposed at the electrically insulative thermal conductivity layer 21 and electrically isolated from one another.

The LED units 41 each comprise an LED chip 42 and a lead wire 44. Each LED chip 42 has a positive electrode 421 and a negative electrode 422. The negative electrode 422 of the LED chip 42 of each LED unit 41 is installed in and electrically connected to one thermal and electric conducting layer 31. The lead wire 44 of each LED unit 41 has one end connected to the negative electrode 422 of the associating LED chip 42 and the other end connected to the positive electrode 421 of the LED chip 42 of another LED unit 41, and therefore the LED chips 42 of the LED units 41 are connected in series.

The packaging device 51 is a transparent packaging compound covering the LED units 41.

In actual practice, an imaginary line should be used to indicate the LED units 41 that are embedded in the transparent packaging compound 51. However, for better indication, a solid line is used in the drawings to indicate the LED units 41 in the transparent packaging compound 51.

As indicated above, the LED chips 42 of the LED units 41 are connected in series. This arrangement increases the demand for voltage at the two ends without increasing the demand for current. Therefore, the invention facilitates the control of the driving power, avoiding the trouble of high current output. Further, because the series connection of the LED chips 42 does not require a high current, the combination of LED and heat dissipating device 10 does not produce extra heat energy. In consequence, the combination of LED and heat dissipating device 10 enables excellent heat dissipation efficiency.

Further, because the LED chips 42 are directly installed in the conducting layers 31 that is covered on the electrically insulative thermal conductivity layer 21 outside the heat dissipating device 11, heat energy that is produced during operation of the LED chips 42 is transferred rapidly from the LED chips 42 through the thermal and electric conducting layers 31 and the electrically insulative thermal conductivity layer 21 to the heat dissipating device 11 for quick dissipation into the outside open air by the radiation fins 12.

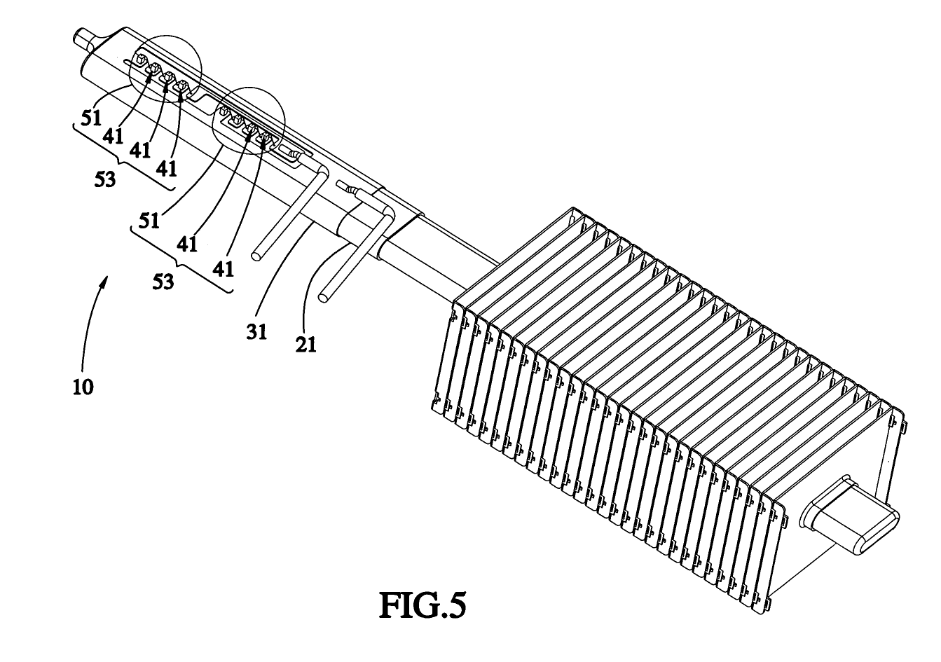

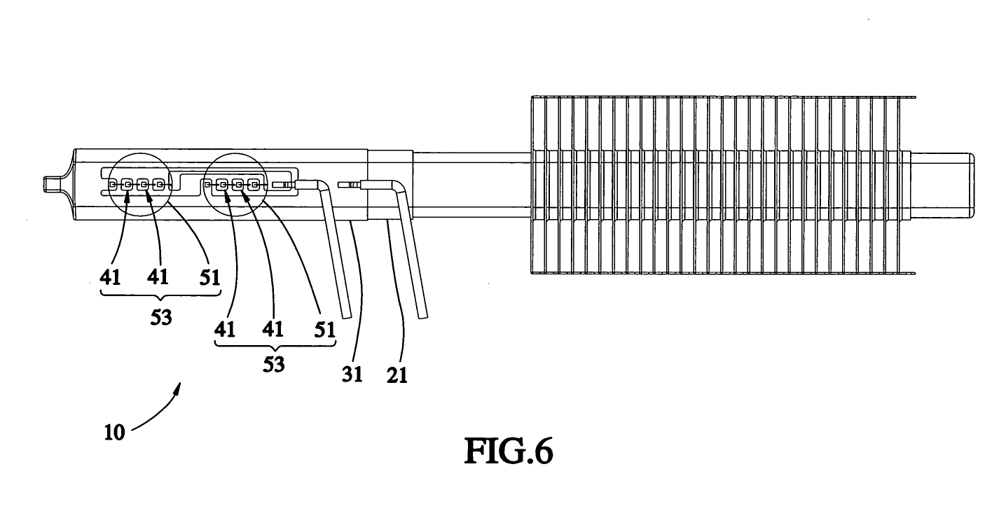

Referring to FIGS. 5 and 6, multiple LED units 41 are arranged into multiple LED series 53, (for example, four LED units 41 form one LED series 53), and each two LED series 53 are connected in parallel.

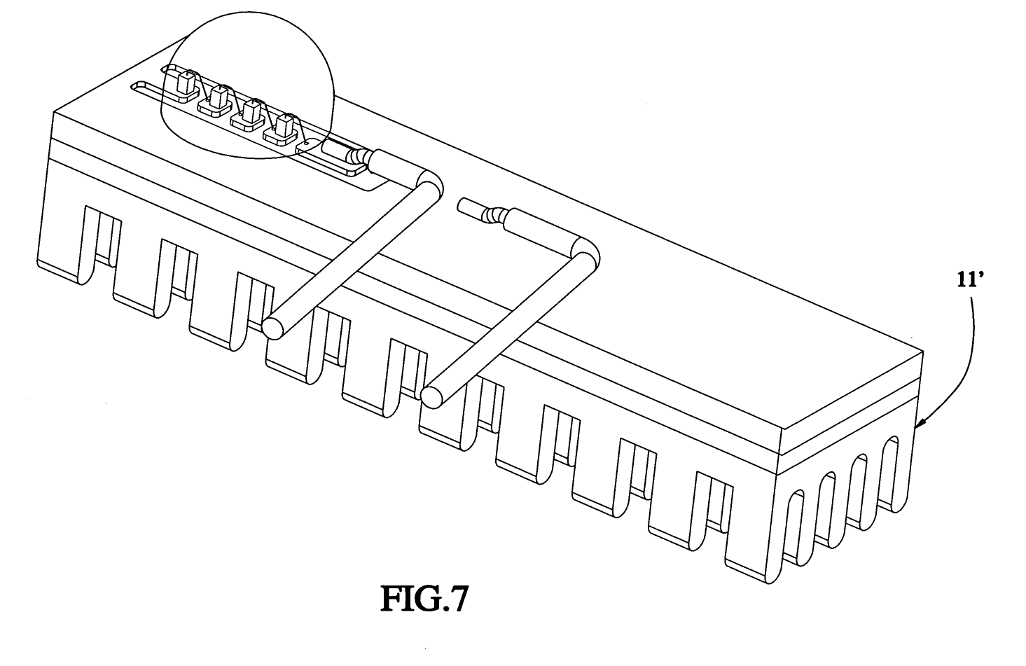

FIG. 7 illustrates an elevational assembly view of a combination of LED and heat dissipating device in accordance with a second embodiment of the present invention. This second embodiment is substantially similar to the aforesaid first embodiment with the exception that the heat dissipating device 11′ of this second embodiment is formed of a heat sink.

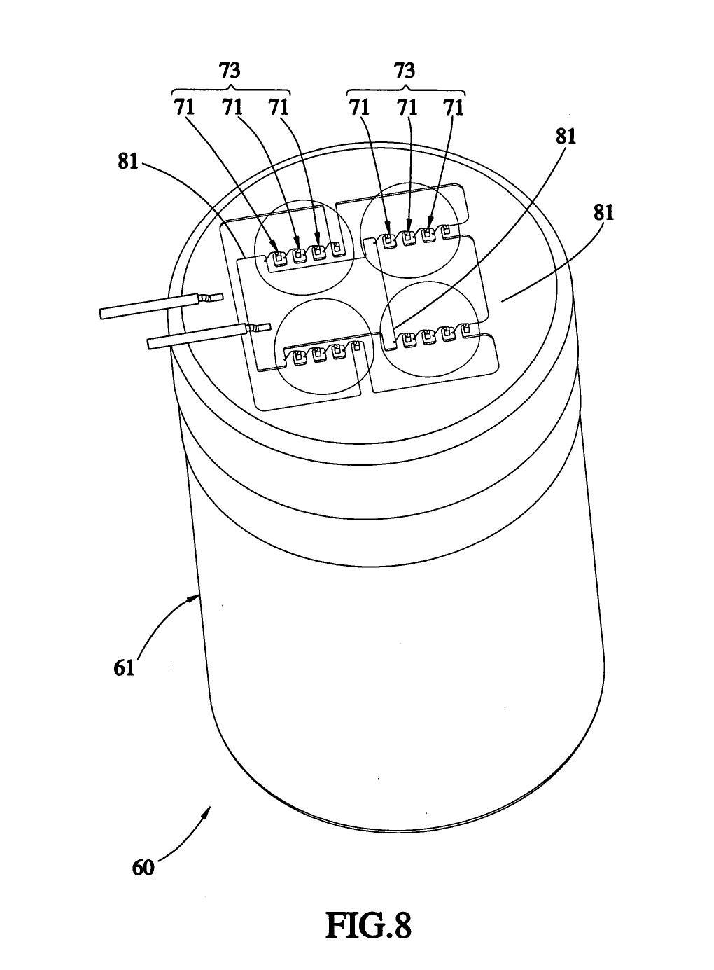

FIG. 8 illustrates a combination of LED and heat dissipation device in accordance with a third embodiment of the present invention. This second embodiment is substantially similar to the aforesaid first embodiment with the exception that the LED units 71 of this second embodiment are installed in one end of the heat dissipating device 61. The LED units 71 are arranged into multiple LED series 73. Each LED series 73 is comprised of multiple, for example, four LED units 71. The LED series 73 are connected in parallel by means of the thermal and electric conducting layers 81.

This third embodiment has a series connection configuration and a parallel connection configuration. The series connection configuration is formed of an LED series 73 each comprised of a series of multiple (for example, four) LED units 71. The parallel configuration is formed of multiple LED series 73 that are connected in parallel. The co-existence of series connection and parallel connection facilitates control of resistance, current and voltage requirements, and therefore the invention facilitates the arrangement of the driving power. Except the above description, the other part and operation manner of this third embodiment are same as the aforesaid first embodiment.

As stated above, the invention achieves the effect of quick transfer of heat energy and the effect of reduction of the demand for power. By means of connecting LED chips in series, the invention avoids the low voltage and high current problem of the conventional parallel connection technique, lowering the requirement for power specification. Further, direct installation of LED chips in the thermal and electric conducting layers allows direct transfer of heat energy from the thermal and electric conducting layers and the electrically insulative thermal conductivity layer to the heat dissipating device for quick dissipation of heat.

The heat dissipating device in either one of the aforesaid three embodiments can be a thermal tube or heat sink. However, it is not a limitation. Various other modifications and enhancements may be made without departing from the spirit and scope of the invention. Accordingly, the invention is not to be limited except as by the appended claims.

What is claimed is:

1. A combination of LED and heat dissipating device comprising:
a heat dissipating device;
an electrically insulative thermal conductivity layer covered on at least a part of the surface of said heat dissipating device;
a plurality of thermal and electric conducting layers disposed at said electrically insulative thermal conductivity layer and electrically isolated from one another;
a plurality of LED units, said LED units each comprising an LED chip and at least one lead wire, the LED chip of each of said LED units being installed in one of said thermal and electric conducting layers, the at least one lead wire of each of said LED units each having one end connected to the LED chip of the respective LED unit and an opposite end connected to the LED chip of another one of said LED units such that the LED chips of said LED units are connected in series; and
at least one packaging device covering said LED units.

2. The combination of LED and heat dissipating device as claimed in claim 1, wherein the LED chips of said LED units each have a positive electrode and a negative electrode; the at least one lead wire of each of said LED units each has one end connected to the negative electrode of the LED chip of the respective LED unit and an opposite end connected to the positive electrode of the LED chip of another one of said LED units.

3. The combination of LED and heat dissipating device as claimed in claim 2, wherein the LED chip of each of said LED units has the negative electrode thereof electrically connected to one of said thermal and electric conducting layer, and the lead wire of each of said LED unit has one end connected to the thermal and electric conducting layer to which the negative electrode associating LED chip is connected and an opposite end connected to the positive electrode of the LED chip of another end of said LED units.

4. The combination of LED and heat dissipating device as claimed in claim 1, wherein the LED chips of said LED units form multiple LED series, each LED series comprised of a number of LED chips that are connected in series, said multiple LED series being connected in parallel by means of the lead wires of the respective LED units.

5. The combination of LED and heat dissipating device as claimed in claim 1, wherein said heat dissipating device is a liquid/gas phase heat dissipating device.

6. The combination of LED and heat dissipating device as claimed in claim 5, wherein said heat dissipating device is a heat tube.

7. The combination of LED and heat dissipating device as claimed in claim 1, wherein said heat dissipating device is a heat sink.

8. The combination of LED and heat dissipating device as claimed in claim 1, wherein said at least one packaging device each is a transparent packaging compound.

9. The combination of LED and heat dissipating device as claimed in claim 1, wherein said heat dissipating device comprises a plurality of radiation fins arranged at one end thereof.
